(19) United States
(12) Patent Application Publication
(10) Pub. No.: US 2003/0001658 A1
(43) Pub. Date: Jan. 2, 2003

(54) Semiconductor device

(76) Inventor: Koichi Matsumoto, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 10/181,999

(22) PCT Filed: Nov. 26, 2001
(86) PCT No.: PCT/JP01/10267

(30) Foreign Application Priority Data
Nov. 28, 2000 (JP) P2000-361603

(51) Int. Cl. H03K 3/01

(52) U.S. Cl. 327/534

(57) ABSTRACT

Disclosed is a MOS-type semiconductor apparatus which adjusts the threshold voltage to a predetermined value, and lowers leak current and reduces power consumption without lowering the operating speed of transistors. The MOS-type semiconductor apparatus (1) formed using an SOI substrate in which a support substrate (3), an insulation layer (buried oxide film) (2), and a semiconductor layer are sequentially layered comprises conductors (N-wells and P-wells) beneath the insulation layer (2), and a threshold-value control circuit which compares a signal f (soi) generated by an oscillator in the semiconductor apparatus to a reference signal f (ref) inputted from outside, and applies bias voltages V_{sub1} and V_{sub2} to the conductors (the N-wells and P-wells) based on the difference between both signals.

### TECHNICAL FIELD

The present invention relates to a technology for optimizing the operating speed and power consumption of transistors by controlling a threshold voltage by way of applying a bias voltage to a support substrate beneath a buried oxide film in a MOS type semiconductor apparatus formed with an SOI substrate.

### BACKGROUND ART

In modern MOS-type semiconductor apparatuses, along with the miniaturization of device dimensions, an increase in operating speed and improvement in low-power consumption are being advanced.

In addition, a decrease in power source voltage has advanced, and the effect the threshold voltage of a transistor has on the operating speed of the transistor or the leak current while turned off is becoming bigger. In other words, as the threshold voltage increases, the leak current while turned off decreases, and power consumption is also reduced, but the operating speed of the transistor becomes slower. Conversely, as the threshold voltage decreases, the operating speed of the transistor becomes faster, but the leak current while turned off increases, and power consumption increases.

On the other hand, the threshold voltage varies to some extent for each chip product. As a result, for a MOS-type semiconductor apparatus, which uses a plurality of chips, as a whole, a loss is incurred in that the design must be adapted to the slowest of the varying operating speeds among the chips.

In relation to such a problem, for a bulk process where source areas and drain areas are formed on the surface of a silicon wafer, a method utilizing the substrate bias effect in order to control the threshold is being studied.

However, when the substrate bias effect is utilized in a bulk process, there are problems in that because the substrate and the source areas or the drain areas have PN-junctions, leak currents in the reverse direction increase, and in that holes generated via impact ionization accumulate in the substrate, causing the substrate potential to change.

Accordingly, the present invention aims at adjusting the threshold voltage to a predetermined value in a MOS-type semiconductor apparatus, decreasing leak currents without reducing the operating speed of the transistors, and lowering power consumption.

### DISCLOSURE OF THE INVENTION

The present inventors discovered that in an SOI (silicon on insulator) type MOS-type semiconductor apparatus, when conductors are provided in a support substrate beneath an insulation layer (a so-called buried oxide film), and a bias voltage is applied to the conductors, because the conductors and the source areas or the drain areas are insulated via the buried oxide film, unlike a case where the substrate bias effect is used in a bulk process, a problem of increased leak currents in the opposite direction does not arise, and further that, when an oscillator is formed in a MOS-type semiconductor apparatus, by comparing signals generated by this oscillator to a reference signal inputted from outside, and by setting a bias voltage based on the difference between both signals, the threshold voltage can be optimized at an arbitrary value.

In other words, the present invention provides a semiconductor apparatus which is a MOS-type semiconductor apparatus formed with an SOI substrate in which a support substrate, an insulation layer and a semiconductor layer are sequentially layered, and which has conductors beneath the insulation layer, and further has a threshold-value control circuit which compares signals formed by an oscillator in the semiconductor apparatus to a reference signal inputted from outside, and applies a bias voltage to the conductors based on the difference between both signals.

### BRIEF DESCRIPTION OF THE DRAWINGS

FIGS. 1A and 1B are a schematic top surface view (FIG. 1A) and a cross sectional view thereof (FIG. 1B) of one example of an embodiment of the present invention.

FIG. 2 is a schematic cross sectional view of another embodiment of the present invention.

FIG. 3 is a block configuration diagram of a threshold value control circuit.

FIG. 4 is a relationship diagram for a bias voltage and a threshold voltage.

### BEST MODES FOR IMPLEMENTING THE INVENTION

Hereinafter, the present invention is described in detail with reference to the drawings. In the drawings, identical reference numerals express identical or equivalent component elements.

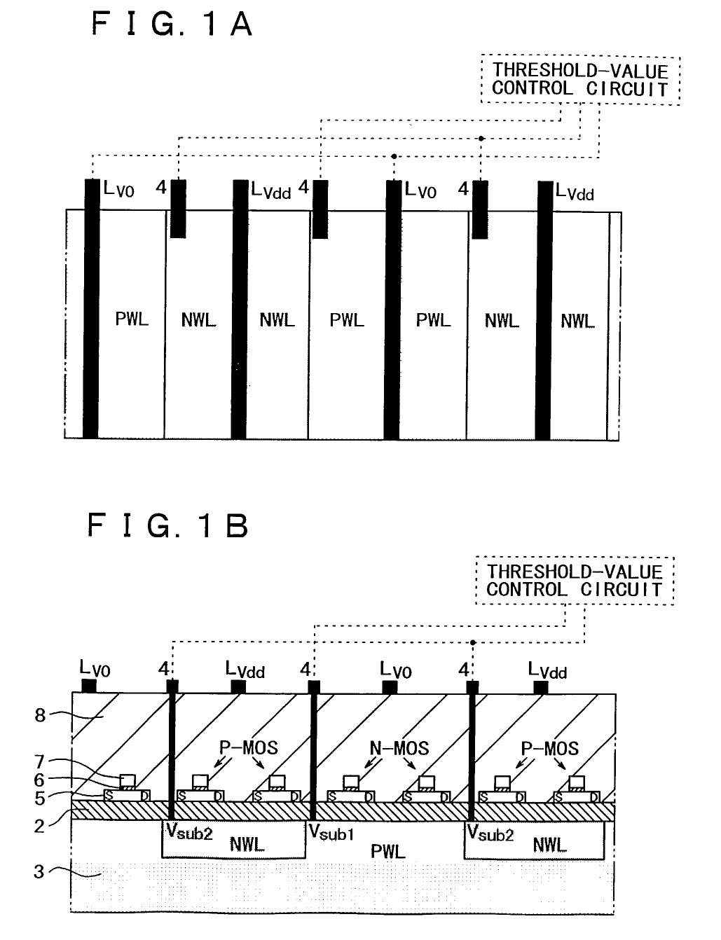

FIG. 1A and FIG. 1B are a schematic top surface view (FIG. 1A) and a cross sectional view (FIG. 1B) of one example of an embodiment where the present invention is applied to a MOS-type semiconductor apparatus of an SOI type having a full-depletion type C-MOS (complementary MOS) transistor.

An SOI type semiconductor apparatus is a semiconductor apparatus formed with an SOI substrate in which semiconductor layers (SOI layers) comprising a support substrate, an insulation layer (buried oxide film), and single-crystal Si are sequentially layered, and it is known that complete isolation of each element becomes easier, and that suppression of soft errors and latch-up which are particular to C-MOS type transistors becomes possible.

In addition, among SOI type semiconductor apparatuses, those which have a full-depletion type transistor in which the SOI layer is reduced to approximately 100 nm in thickness, and in which the entire SOI layer is substantially depleted by controlling the impurity density of a channel formed in the SOI layer directly beneath a gate electrode to a relatively low state have superior characteristics such as reduced diffused layer capacitance and a sharp rise of drain current in the sub-threshold area, and practical application to portable electronic apparatuses is expected.

A MOS-type semiconductor apparatus 1 shown in FIGS. 1A and 1B is a MOS-type semiconductor apparatus comprising a full-depletion type C-MOS transistor to which the construction of the present invention is applied. By applying the construction of the present invention to a semiconductor apparatus comprising a full-depletion type transistor, it is possible to effectively control the threshold voltage by applying a bias voltage, and thus it is quite desirable.

The MOS-type semiconductor apparatus 1 shown in FIGS. 1A and 1B differs from conventional SOI-type semiconductor apparatuses in that in order to enable application of bias voltages V_{sub1} and V_{sub2}, it comprises P-wells (PWL) and N-wells (NWL) as conductors in a support substrate 3 beneath a buried oxide film 2, and in that terminals 4 to which a bias voltage is applied are pulled out to the upper surface, and it also differs in that a threshold-value control circuit is provided between the terminals 4 and earth lines L_{V0} drawn out from the P-wells (PWL) or the N-wells (NWL) so that the predetermined bias voltages V_{sub1} and V_{sub2} can be applied between them.

On the other hand, P-MOS transistors or N-MOS transistors comprising a source area S and a drain area D formed with an SOI layer 5 on the buried oxidized film 2 and a gate electrode 7 formed thereon via a gate oxide film 6 is constructed in a manner similar to full-depletion type SOI-type C-MOS type semiconductor apparatuses of public knowledge. An interlayer insulation film 8 is formed on the P-MOS transistors and the N-MOS transistors, on which power-supply wirings L_{Vdd} and the earth lines L_{V0} are provided. Note that in the figures, wirings formed in the inter-layer insulation film 8 are omitted.

Such a MOS-type semiconductor apparatus 1 can be obtained by, for example, performing device isolation through the trench method on the SOI substrate based on the SIMOX (separation by implanted oxygen) method, forming the P-wells (PWL) and the N-wells (NWL) by way of ion implantation via the buried oxide film 2, and subsequently forming the N-MOS transistors or the P-MOS transistors by conventional methods. In other words, after forming the P-wells (PWL) and the N-wells (NWL), the gate oxide film 6 is formed via thermal oxidation of the surface of the SOI layer 5, the gate electrode 7 is formed thereon, LDD areas, the source areas S, and the drain areas D are formed via ion implantation with the gate electrode 7 as a mask, the inter-layer insulation film 8 is layered, and the various wirings and terminals 4 are formed.

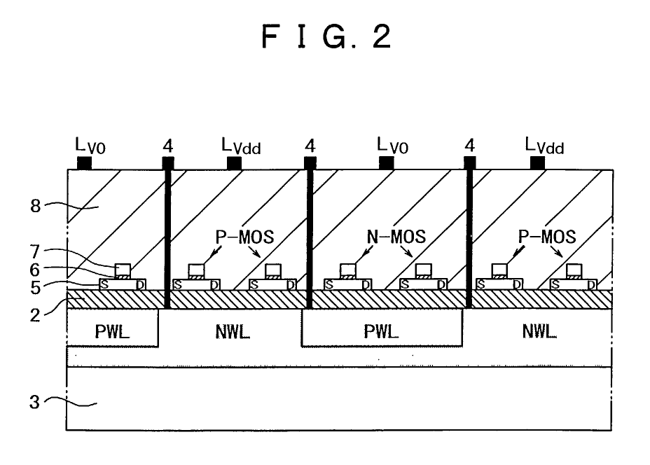

In forming the P-wells (PWL) and the N-wells (NWL), it is preferable that the polarity of impurities be set such that the P-wells (PWL) and the N-wells (NWL) become accumulated layers (accumulation) in accordance with the values of the bias voltages V_{sub1} and V_{sub2} applied thereto. Further, in a case where the support substrate 3 is earthed, it is preferable that the support substrate 3 be formed with a triple-well structure, as shown in FIG. 2.

For the gate electrode 8, it is preferable that N-type or P-type polysilicon, or a high-melting point metal such as W, Ti or a high-melting point intermetallic compound such as TiN having work functions around the mid-gap of Si be utilized.

As shown in FIGS. 1A and 1B, in a C-MOS construction in which the N-MOS and the P-MOS are alternately disposed, it is preferable that bias voltages V_{sub1} and V_{sub2} appropriate for each row of the P-wells (PWL) and the N-wells (NWL) be applied simultaneously. In this case, it is preferable, ordinarily, that the bias voltage V_{sub1} applied to the P-wells (PWL) and the bias voltage V_{sub2} applied to the N-wells (NWL) be set such that V_{sub1}=−V_{sub2}.

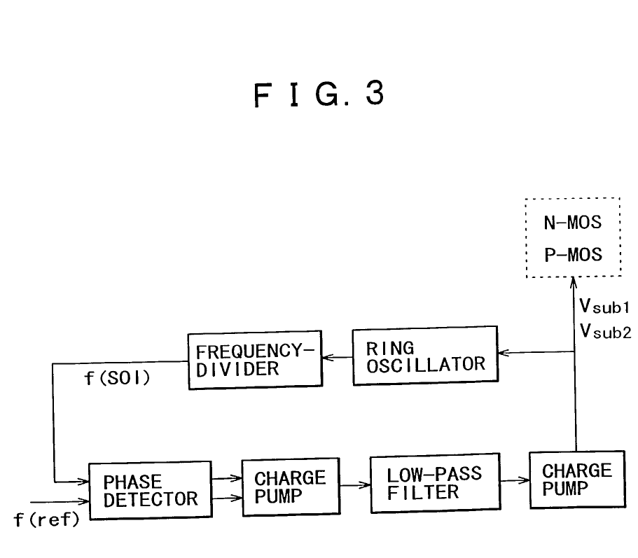

FIG. 3 is a block configuration diagram of a threshold-value control circuit utilized in the MOS-type semiconductor apparatus shown in FIGS. 1A and 1B. This threshold-value control circuit is an application of a publicly known AFC (Automatic Frequency Control) circuit, and it comprises a ring oscillator which oscillates signals based on drive currents of an arbitrary N-MOS or P-MOS transistor in the semiconductor apparatus, a frequency divider which down-converts the oscillation frequency of the ring oscillator, a phase detector into which signals f (SOI) from the frequency divider and reference signals f (ref) of a constant frequency from outside are inputted, a charge pump (Charge Pumping) circuit which enables the application of bias voltages at a voltage higher than the power source voltage, and a low-pass filter.

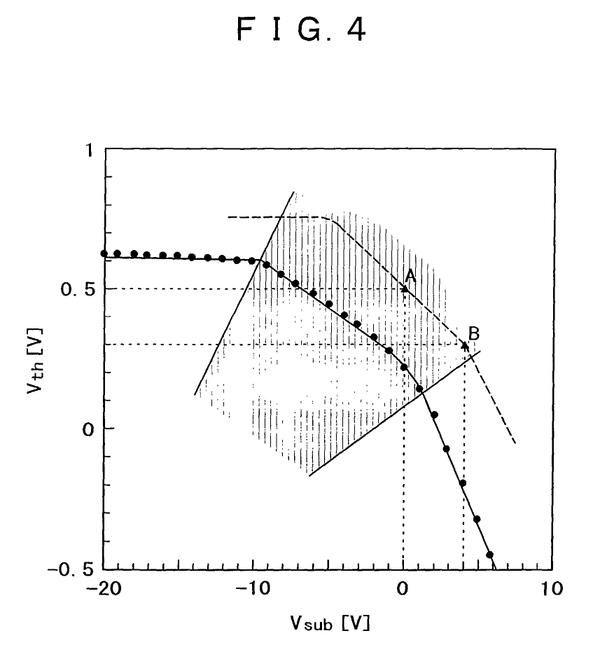

On the other hand, when the relationship between the bias voltage V_{sub} and the threshold voltage Vₜₕ of a full-depletion type N-MOS transistor is simulated, the results shown in FIG. 4 are obtained. Conditions for this simulation are T_{OX}/T_{SOI}/T_{BOX}=3.5/30/100 nm, threshold value judging current=0.1 μA/μm. Further the dotted line is a relationship diagram for the bias voltage V_{sub} and the threshold voltage Vₜₕ generated by variations in physical dimensions. The area marked by oblique lines is a normal operating range of the N-MOS transistor.

As such, the threshold-value control circuit compensates for variations in the threshold voltage Vₜₕ caused by variations in the manufacture of chips or by the in-use environment by optimizing the bias voltages V_{sub1} and V_{sub2} applied to the P-wells (PWL) or the N-wells (NWL), and adjusts the threshold voltage Vₜₕ such that it is within the normal operating range of a transistor. For example, with respect to an N-MOS chip whose threshold voltage Vₜₕ is high, leak current is low, operating speed is slow, and thus whose signal f (SOI) is slow, when the initial bias voltage V_{sub} is 0V (refer to dot A shown in FIG. 4), if a difference between the signal f (SOI) and the reference signal f (ref) is detected by the phase detector, the bias voltage V_{sub} applied to the N-MOS chip from the charge pump circuit becomes 4V, and a predetermined operating speed (refer to dot B shown in FIG. 4) can be obtained. In addition, when a predetermined operating speed is already obtained, a difference between the signal f (SOI) and the reference signal f (ref) is not detected by the phase detector. Accordingly, in this case, the bias voltage applied from the charge pump circuit is held at 4V.

The present invention is not limited to the modes described above, and may take various modes. For example, conductors in a support substrate to which a bias voltage is applied are not only limited to wells formed via ion implantation in the support substrate, but may also be back gate electrodes formed beneath the buried oxide film.

Further, the present invention can be applied to semiconductor apparatuses comprising long-channel transistors, and is not limited to full-depletion type transistors whose thickness of the SOI layer is roughly 100 nm or below.

According to the MOS-type semiconductor apparatus of the present invention, because the optimal threshold voltage can be set depending on the required operating speed and the like regardless of variations in manufacture among the chips or of changes in temperature, leak current can be reduced and power consumption can be lowered without lowering the operating speed of the transistors. Further, because the margin of irregularity during design can thus be estimated to be less, it is possible to enhance the minimum operating speed of the chips.

1. A semiconductor apparatus which is a MOS-type semiconductor apparatus formed using an SOI substrate formed with a support substrate, an insulation layer, and a semiconductor layer sequentially layered, comprising:
a conductor beneath said insulation layer; and
a threshold-value control circuit which compares signals generated by an oscillator in said semiconductor apparatus to a reference signal inputted from outside, and applies a bias voltage to said conductor based on the difference between both signals.

2. The semiconductor apparatus according to claim 1, wherein said conductor beneath said insulation layer includes a well formed by ion implantation to said support substrate.

3. The semiconductor apparatus according to claim 1 or claim 2, wherein said semiconductor apparatus is of a C-MOS (Complementary MOS) type in which both a P-well and an N-well are formed on said support substrate, and a bias voltage is simultaneously applied to said P-well and said N-well.

4. The semiconductor apparatus according to one of claim 1˜claim 3, wherein a full-depletion type MOS-type transistor is formed.

5. The semiconductor apparatus according to one of claim 1˜claim 4, further comprising a charge pump circuit for enabling application of a bias voltage at a voltage higher than a power source voltage.
